(19) United States
(12) Patent Application Publication
(10) Pub. No.: US 2026/0282424 A1
(43) Pub. Date: Sep. 17, 2026

(54) INTEGRATED CIRCUIT DEVICE AND METHOD OF MANUFACTURING THE SAME

(71) Applicant: Taiwan Semiconductor Manufacturing Company, Ltd., Hsinchu (TW)

(72) Inventors: Ta-Chuan Liao, Taichung City (TW); Wen-Ling Lu, Taoyuan County (TW); Yu-Chien Chiu, Hsinchu County (TW); Ya-Yun Cheng, Taichung City (TW); Zhiqiang Wu, Hsinchu County (TW)

(21) Appl. No.: 19/079,558

(22) Filed: Mar. 14, 2025

(51) Int. Cl. H10D 30/00; H10B 10/00; H10B 12/00; H10D 30/01; H10D 62/10; H10D 62/80

(52) U.S. Cl. CPC H10D 30/502; H10D 30/0191; H10D 62/121; H10B 10/125; H10B 12/30; H10D 62/875

(57) ABSTRACT

In some embodiments, the present disclosure relates to an IC device including an array of cells, each including a stacked field-effect transistor (FET) that includes a gate stack, a channel layer, source and drain terminals, and dielectric layers. The gate stack includes top and bottom gate boards and a gate pillar conductively connecting them. The channel layer includes a first channel band disposed between the bottom gate board and the top gate board and connecting the source terminal to the drain terminal. The source terminal is located on a first side of the gate stack and the drain terminal is located on a second side of the gate stack. A bottom-gate dielectric layer separates the bottom gate board from the channel layer and a top-gate dielectric layer separates the top gate board from the channel layer. The gate stack is configured to control the conductivity of the first channel band.

### BACKGROUND

Systems of integrated-circuit (IC) transistors, particularly field-effect transistors (FETs) have been increasing in density as manufacturers aim to provide new generations of devices having greater storage capacity and/or computing power at lower relative costs.

Accordingly, typical FETs have evolved from planar devices having sources, drains, and channels embedded in a substrate with the gate abutting the channel to three-dimensional FETs such as finFETs, which have fin-like channels outside of the substrate with the transistor gate bracketing on three sides the channel between the source and the drain.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion. Relatedly, proportions of illustrated elements may vary among different figures.

FIG. 1A illustrates a simplified oblique projection view of an example stacked FET of an example cell of an array of cells in accordance with some embodiments of the disclosure.

FIG. 1B illustrates a simplified cross-section view in the x-z plane of an alternative implementation of a cell in an array of cells in accordance with some embodiments of the disclosure.

FIGS. 2-13C show simplified views of various example stages of manufacture of portions of an example integrated circuit (IC) device in accordance with some embodiments of the disclosure.

FIG. 13D illustrates a simplified circuit diagram of an example 1T1C memory cell that may, for example, correspond to the memory cells of FIGS. 13A, 13B, and 13C.

FIG. 14A illustrates a simplified circuit diagram of an example 2TOC memory cell that may correspond to example memory cells described below.

FIG. 14B illustrates a simplified cross-sectional view of an example memory array portion comprising a pair of 2T0C memory cells in accordance with some embodiments of the disclosure.

FIG. 15 illustrates a simplified cross-sectional view of an example memory array portion that comprises two 2T0C memory cells whose read transistors do not share a drain.

FIG. 16 illustrates a simplified oblique perspective view of an example FET corresponding to a write transistor of FIG. 14B.

FIG. 17 illustrates a simplified oblique perspective view of an alternative example FET corresponding to a write transistor of FIG. 14B.

FIGS. 18A-20B show simplified views of various example stages of manufacture of portions of an example integrated circuit (IC) device in accordance with some embodiments of the disclosure.

FIG. 21 illustrates a simplified cross-sectional view of an example cell in accordance with an alternative embodiment of the disclosure.

FIG. 22 illustrates a simplified cross-sectional view an example cell in accordance with another alternative embodiment of the disclosure.

FIG. 23 illustrates a simplified cross-sectional view of an example cell in accordance with an alternative embodiment of the disclosure.

FIG. 24 illustrates a simplified cross-sectional view of an example cell in accordance with an alternative embodiment of the disclosure.

FIG. 25 is a flowchart illustrating an example method of forming an IC device in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

In addition to the developments noted above, another recent development promoting denser transistor arrays has been gate-all-around FETs (GAAFETs), where the channels are shaped from nanosheets and sacrificial layers formed over the substrate, using photolithographic etching, followed by channel release operations removing the sacrificial material. The channels are then surrounded on all sides by insulator and gate material, using atomic layer deposition (ALD), to form gate-all-around transistors. Using GAAFETs allows for reducing the transistor dimensions while providing greater control of the channel characteristics, such as conductivity or flow of carriers, by the gate. Consequently, more transistors can be fit in a given area while meeting desired performance goals. Importantly, fabricating GAAFETs typically employs high-temperature annealing to achieve desired device properties, performed as part of a front-end-of-line (FEOL) process flow.

Additional recent developments in increasing device density have involved thin-film transistor (TFT) technology, which allows the fabrication of three-dimensional device arrays by forming transistors in the back-end-of-line (BEOL) layers overlaying transistors in the FEOL layers. This allows, for example, fabricating integrated devices combining processor logic modules in the FEOL layers with memory (e.g., random access memory (RAM)) arrays in the BEOL layers. Such integrated systems may be referred to as compute-in-memory, in-memory computing, logic-in-memory, logic-memory integrated, or monolithic devices, or other similar terms. Notably, this integration allows these devices to overcome some of the data transfer bottlenecks faced by traditional (e.g., von-Neumann) architectures.

Initially, BEOL layers were used for routing metallization lines interconnecting FEOL devices. However, advances in materials and techniques have made possible the fabrication of active devices, in addition to routing lines, in the BEOL layers. These advances have included the adoption of metal-oxide semiconductor (MOS) materials, also referred to as oxide semiconductors, for the transistor channels. Notably, oxide semiconductors are better suited for back-end-of-line (BEOL) processes than traditional semiconductor materials since, for example, they are more compatible with the lower thermal budgets of BEOL processes.

Significantly, naively combining features of TFTs and GAAFETs by, for example, attempting channel release operations on MOS channels, which are fragile and susceptible to damage from etching, would result in collapsed or otherwise damaged channels-and, consequently, inoperative devices.

Some embodiments of the disclosure are directed to IC devices including memory arrays that are integrated with FETs formed using gate release fabrication operations, where these FETs have stacked gate structures and MOS channels. The FETs include a vertical stack of horizontally parallel gate boards, each gate board surrounded, at least partially, by a metal-oxide-semiconductor channel layer, where the source and drain are disposed laterally of the gate and channel stack. These FETs may be referred to as stacked-gate FETs. The stacked gate structure allows for reduced dimensions, both in width and length, while maintaining desired performance characteristics. The reduced dimensions allow tighter bitline and wordline pitches in a corresponding memory array-in other words, greater device density. Similarly, the stacked structure can allow improving transistor performance characteristics while maintaining device density. Relatedly, increasing the number of channels allows for a higher on-state current (I_{ON}).

Relevant performance characteristics include, for example, gate control, threshold voltage, on-state current (I_{ON}), off-state current (I_{OFF}), and subthreshold swing (SS). The subthreshold swing value provides a measure of the efficiency of a transistor's switch from the off state to the on state. It is typically measured as the gate voltage (V_{GS}) required to change the drain current (I_{D}) by one order of magnitude (e.g., by a multiplicative factor of ten), generally expressed as millivolts per decade (mV/dec). A lower subthreshold swing value is generally considered better.

The off-state current (I_{OFF}) of a transistor is the drain-source current when the gate voltage is below its threshold and generally corresponds to the transistor's leakage current. A lower off-state current indicates a lower leakage current and is generally considered better. The on-state current (I_{ON}) of a transistor is the drain-source current when the transistor is in its on state and the gate voltage is above its threshold. A higher on-state current allows for faster switching and is generally considered better. In view of the above, a higher I_{ON}/I_{OFF} ratio and is generally considered better.

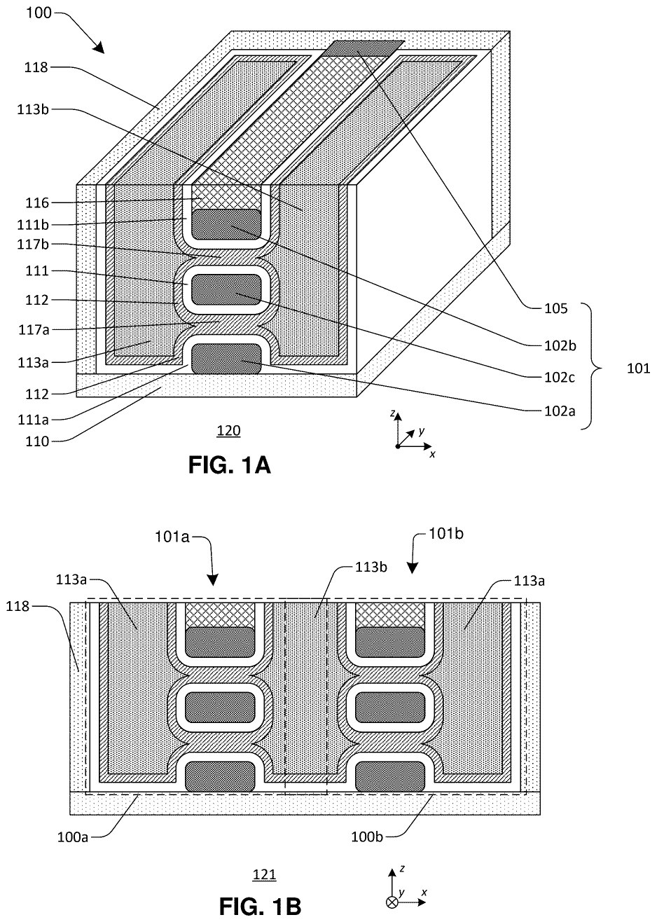

FIG. 1A illustrates a simplified oblique projection view of an example stacked FET 100 of an example cell 120 of an array of cells (not shown), in accordance with some embodiments of the disclosure. Note that example coordinate axes are provided throughout the drawings to assist in understanding of the drawings and are intermittently referenced below. The stacked FET 100 is formed over a base layer 110. The base layer 110 may be substantially an insulator such as, for example, silicon dioxide (SiO₂) or any other suitable base-layer material, which, notably, may contain routing lines or vias and, furthermore, may include and/or overlay layers (e.g., a substrate) including active devices. Accordingly, in some implementations, the base layer 110 comprises mostly an inter-layer dielectric (ILD) formed over a semiconductor substrate. In general, ILD may include, for example, silicon dioxide (SiO₂), silicon nitride (Si₃N₄), silicon oxynitride, carbon doped silicon oxide, other suitable dielectric materials, or combinations thereof.

The stacked FET 100 includes a gate stack 101 comprising a gate pillar 105 and a plurality of substantially parallel and substantially identical gate boards 102. The plurality of gate boards 102 includes a bottom gate board 102a, a top gate board 102b, and an intermediary gate board 102c. Each gate board 102 resembles a board or plank having a major axis along the y direction, a lateral axis along the x direction, and a minor axis along the z direction. The cross-section of a gate board 102 in the x-z plane may be substantially rectangular, e.g., a rounded rectangle. The bottom gate board 102a is at the bottom of the gate stack 101, overlaying and contacting the base layer 110. The intermediary gate board 102c overlays the bottom gate board 102a at an offset, while the top gate board 102b overlays the intermediary gate board 102c at substantially the same offset. The gate pillar 105 has a major axis along the z direction and is conductively and structurally connected to each of the gate boards 102. The gate stack 101 may conductively connect to gate-control circuit elements via the gate pillar 105. In addition, the gate pillar 105 may provide structural support to the gate boards 102 during fabrication, as described further below. The gate stack is made of a conductive material such as, for example, titanium (Ti), titanium nitride (TiN), tungsten (W), tantalum nitride (TaN), copper (Cu), aluminum (Al), doped polysilicon, or any other suitable conductive material.

A hardmask board 116 overlays and is in contact with the top gate board 102b. The hardmask board 116 is a remnant of a hardmask layer used in the fabrication of the stacked FET 100, as described further below, used, e.g., for feature patterning and as a polish stop for planarization (e.g., chemical mechanical planarization (CMP)). The hardmask board 116 may have a similar same cross-section in the x-y plane to the gate boards 102. The hardmask board 116 may comprise, for example, silicon nitride (Si₃N₄), aluminum oxide (Al₂O₃), amorphous silicon, polysilicon, or any other suitable hardmask material.

The gate boards 102 are overcoated across surfaces, not otherwise in contact with other elements, by a dielectric layer 111. The dielectric layer 111 is itself in turn overcoated with a channel layer 112. The channel layer 112 includes channel bands 117 disposed between sequential gate boards 102. For example, the channel layer 112 of FIG. 1A includes (1) a first channel band 117a disposed between the bottom gate board 102a and the intermediary gate board 102c and (2) a second channel band 117b disposed between the intermediary gate board 102c and the top gate board 102b. It should be noted that, in view of the arrangement of the gate boards 102, each of channel bands 117a and 117b is also disposed between the bottom gate board 102a and the top gate board 102b.

The dielectric layer 111 provides electric isolation between the gate stack 101 and the channel layer 112. The dielectric layer 111 includes (1) a bottom-gate dielectric section 111a separating the bottom gate board 102a from the channel layer 112 and (2) a top-gate dielectric section 111b separating the top gate board 102b from the channel layer 112. The dielectric layer 111 may comprise a high-k dielectric material, such as, for example, hafnium oxide (HfO2), zirconium oxide (ZrO₂), aluminum oxide (Al₂O₃), magnesium oxide (MgO), hafnium silicon oxide (HfSiO), silicon oxynitride (SiON), hafnium silicon oxynitride (HfSiON), hafnium tantalum oxide (HfTaO), hafnium titanium oxide (HfTiO), hafnium titanium tantalum oxide (HfTiTaO), hafnium aluminum oxynitride (HfAlON), hafnium zirconium oxide (HfZrO), other suitable dielectric materials (including low-k dielectric materials such as SiO₂), or combinations thereof.

As noted above, the channel layer 112 comprises a metal oxide semiconductor.

Specifically, the channel layer 112 may comprise an n-type MOS such as, for example, indium gallium zinc oxide (InGaZnO, sometimes also abbreviated as IGZO), indium tungsten oxide (IWO), indium oxide (In₂O₃), tin dioxide (SnO₂), zinc oxide (ZnO), or any suitable n-type metal oxide semiconductor. Alternatively, the MOS channel layer 112 may comprise a p-type MOS such as, for example, tin oxide (SnO), nickel oxide (NiO), copper oxide (Cu₂O), copper aluminum oxide (CuAlO₂), copper gallium oxide (CuGaO₂), copper indium oxide (CuInO₂), strontium copper oxide (SrCu₂O₂), or any suitable p-type metal oxide semiconductor.

The stacked FET 100 further includes current-carrying terminals 113a and 113b, one of which may function as a source (e.g., source 113a) and the other of which may function as a drain (e.g., drain terminal 113b). Current-carrying terminals 113 may also be referred to as source/drain terminals. The source terminal 113a is located on a first side of the gate stack 101, while the drain terminal 113b is located on a second side of the gate stack 101. The channel bands 117 connect the source terminal 113a to the drain terminal 113b, wherein the conductivity of the channel bands 117 is controlled by the voltage level of the gate stack 101. The current-carrying terminals 113 may comprise conductive materials such as, for example, titanium nitride (TiN), tungsten (W), tantalum nitride (TaN), copper (Cu), aluminum (Al), cobalt (Co), ruthenium (Ru), doped polysilicon, or any other suitable conductive material. As noted above, the structure and materials of the stacked FET 100 provide for a high level of gate control over the channel, with superior operating characteristics such as, for example, subthreshold swing, on-state current, and off-state current.

The FET 100 is separated from adjoining structures—e.g., other FETs 100 and/or cells 120—by a barrier 118. It should be noted that while the figure shows the barrier 118 on two lateral sides, it would be present on all four lateral sides. The barrier 118 may be an isolation barrier comprising, for example, silicon dioxide, or any other suitable material. It should be noted that surfaces of the barrier 118, as well as surfaces of the base layer 110, may also be overcoated with the dielectric layer 111 and the channel layer 112. These overcoat layers over barriers and base layers may be artifacts of the fabrication process, may lack a significant functional role, and may optionally be partially or wholly removed and/or absent.

FIG. 1B illustrates a simplified cross-section view in the x-z plane of an alternative implementation of a cell 121 in an array of cells in accordance with some embodiments of the disclosure. While the cell 120 of FIG. 1A includes one stacked FET 100, the cell 121 of FIG. 1B includes two stacked FETs 100, namely stacked FETs 100a and 100b, indicated by the dashed outlines in the drawing. The stacked FET 100a, which comprises the gate stacks 101a, is substantially similar to the stacked FET 100 of cell 120. The stacked FET 100b, which comprises the gate stacks 101b, is substantially similar to a mirrored stacked FET 100 of cell 120 in as much as the locations of the source terminal 113a and drain terminal 113b are reversed.

Notably, the stacked FETs 100a and 100b share the drain terminal 113b. Consequently, the drain terminal 113b may be referred to as a shared drain and the cell 121 may be referred to as a shared-drain cell. Relatedly, while in the stacked FET 100 of cell 120 of FIG. 1A the drain terminal 113b is located between the gate stack 101 and the barrier 118 (not shown), in the stacked FETs 100a and 100b of cell 121 of FIG. 1B the shared drain terminal 113b is located between the gate stacks 101a and 101b.

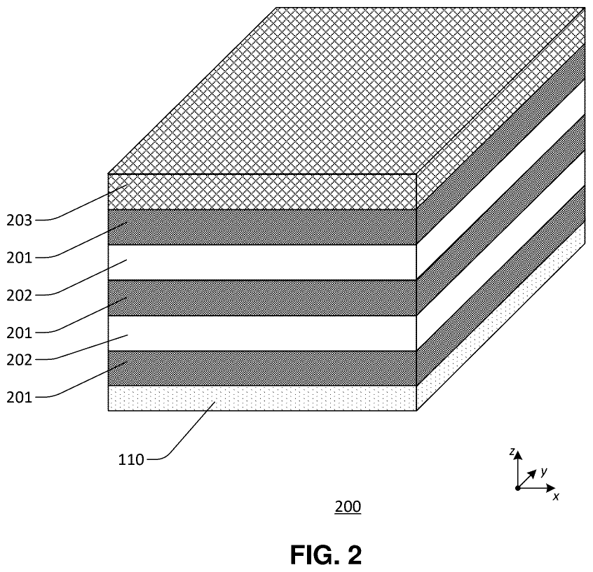

FIGS. 2-13 show simplified views of various example stages of manufacture of portions of an example integrated circuit (IC) device in accordance with some embodiments of the disclosure. Although these figures are described as a series of acts, it will be appreciated that these acts are not limiting in that the order of the acts can be altered in other embodiments, and the methods disclosed are also applicable to other structures. In some embodiments, some acts that are illustrated and/or described may be omitted in whole or in part. In some embodiment, additional acts that are not described herein may also be performed as part of the manufacturing process.

FIG. 2 illustrates a simplified oblique projection view of an example portion 200 of an integrated circuit following the deposition on a base layer 110 of layers of gate material 201, wherein the layers of gate material 201 are separated by sacrificial layers 202 and the top layer of gate material 201 is overlayed with a hardmask layer 203. The gate boards 102 will be formed from corresponding layers of gate materials 201 and the hardmask board 116 will be formed from the hardmask layer 203. The base layer 110 may comprise any of the above-listed base-layer materials. Similarly, the layers of gate material 201 may comprise any of the above-listed gate materials, while the hardmask layer 203 may comprise any of the above-listed hardmask materials. In some implementations, the gate-material layers may be about 5 nm thick, the sacrificial-material layers may be about 10 nm thick, and the hardmask layer may be about 10 nm thick. Note that the thickness of the sacrificial layers should be made sufficient, in view of the thickness of the dielectric layer, to allow the formation of the channel bands of the channel layer during the deposition of the channel layer, as described further below.

The sacrificial layers 202 comprise a material having a significantly higher etch rate than the gate material 201 and the hardmask layer 203. The combination options vary based on the particular materials and etchant. For example, in some embodiments, Si₃N₄ may be used as the sacrificial material alongside TiN as the gate material and Al₂O₃ as the hardmask material since the etch rate of optional wet-etchant phosphoric acid (H₃PO₄)—particularly, hot phosphoric acid—for Si₃N₄ is more than about twenty times greater than for TiN and Al₂O₃. The various layer materials may be deposited using, for example, atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, spin-on techniques, other suitable processes, and/or combinations thereof. In some implementations, the sacrificial material may be aluminum, or any other suitable sacrificial material.

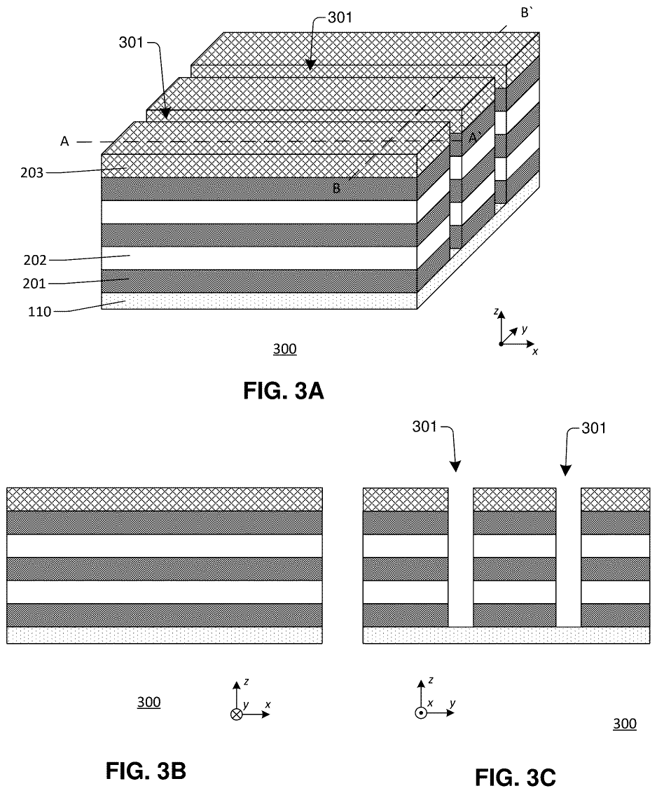

FIG. 3A illustrates a simplified oblique view of a portion 300, corresponding to the portion 200 of FIG. 2 following the formation of a first set of trenches 301 through the gate materials 201, sacrificial layers 202, and hardmask layer 203. FIG. 3B illustrates a cross-sectional view of the portion 300 along the cut line A-A′ of FIG. 3A. FIG. 3C illustrates a cross-sectional view of the portion 300 along the cut line B-B′ of FIG. 3A. The trenches 301 may be formed, for example, by a photolithographic etching process including patterning using a photolithographically developed photoresist, then etched using, for example, a dry etchant using a fluorine-containing gas (e.g., xenon fluoride (XeF₆), sulfur fluoride (SF₆), carbon fluoride (CF₄), or other suitable gas. Similar processes may be used for similar fabrication steps described below.

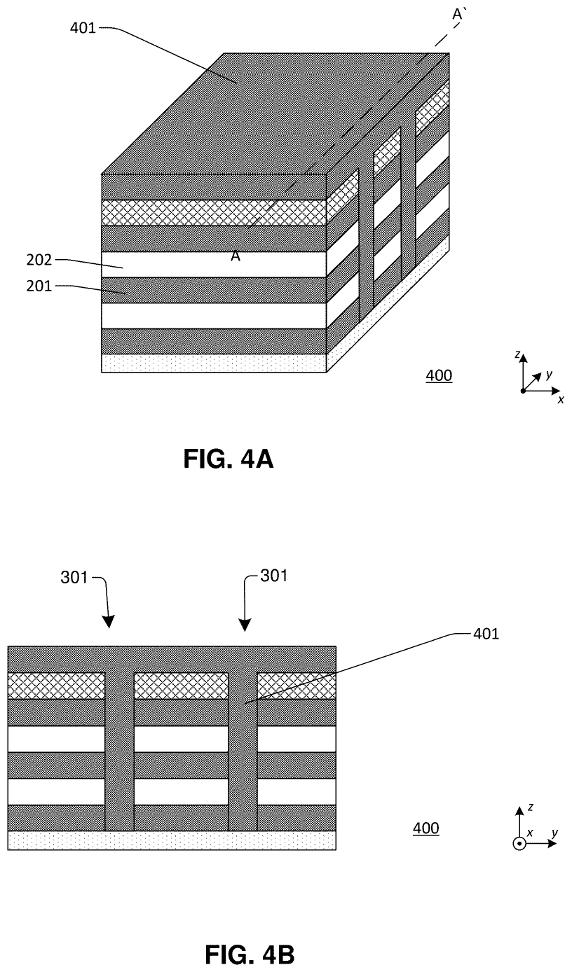

FIG. 4A illustrates a simplified oblique view of a portion 400, corresponding to the portion 300 of FIG. 3A after the deposition of gate pillar material 401 over the hardmask layer 203, filling the first set of trenches 301. FIG. 4B illustrates a cross-sectional view of the portion 400 along the cut line A-A′ of FIG. 4A. The gate pillar material 401 may comprise any of the above-listed conductive gate materials.

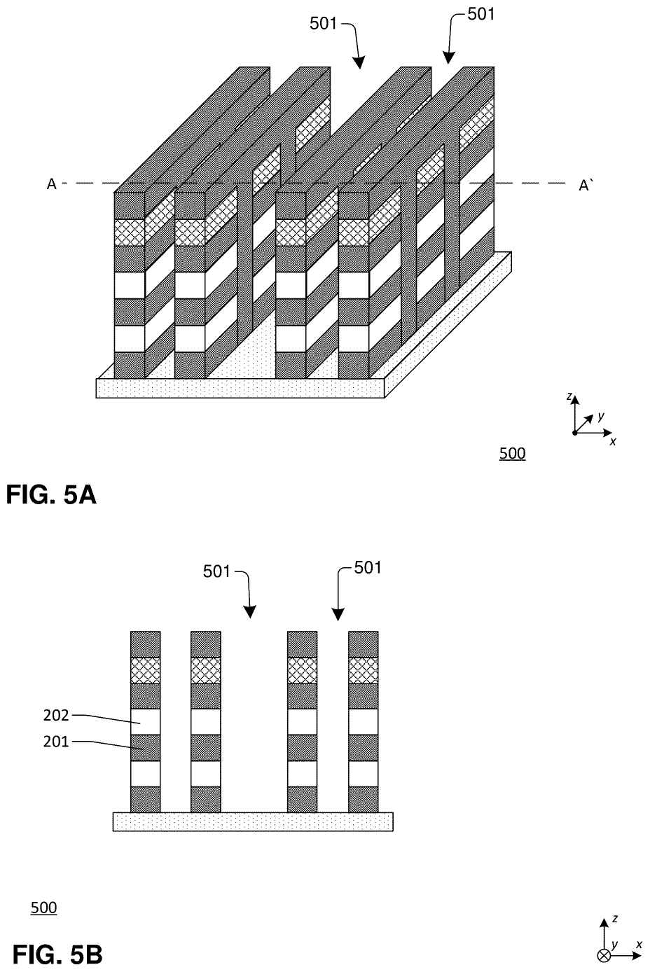

FIG. 5A illustrates a simplified oblique view of a portion 500, corresponding to the portion 400 of FIG. 4A after the formation of a second set of trenches 501 through the gate pillar material 401, hardmask layer 203, gate material layers 201, and sacrificial layers 202. FIG. 5B illustrates a cross-sectional view of the portion 500 along the cut line A-A′ of FIG. 5A. The second set of trenches 501, which are perpendicular to the first set of trenches 301, may be formed by an etching process as described above.

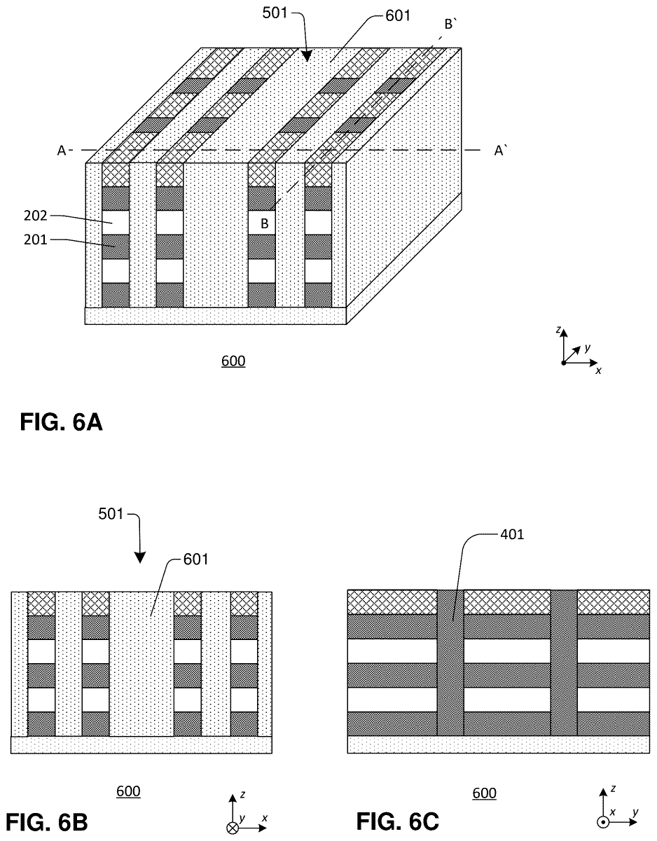

FIG. 6A illustrates a simplified oblique view of a portion 600, corresponding to the portion 500 of FIG. 5A after the deposition of dielectric material 601 filling the trenches 501 and the planarization of the resultant portion. FIG. 6B illustrates a cross-sectional view of the portion 600 along the cut line A-A′ of FIG. 6A. FIG. 6C illustrates a cross-sectional view of the portion 600 along the cut line B-B′ of FIG. 6A.

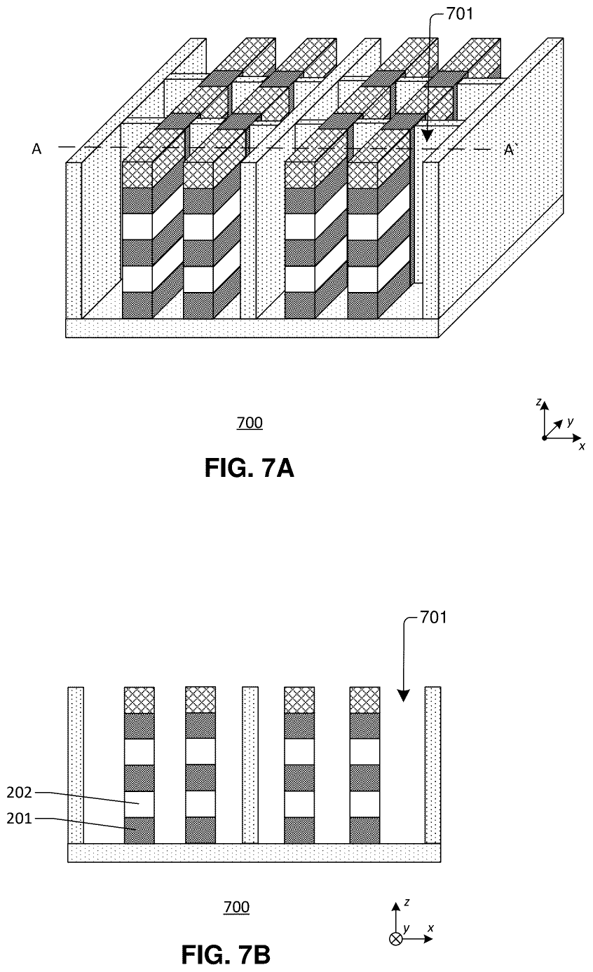

FIG. 7A illustrates a simplified oblique view of a portion 700, corresponding to the portion 600 of FIG. 6A after the formation of cavities 701 through the hardmask layer 203, gate material layers 201, and sacrificial layers 202. FIG. 7B illustrates a cross-sectional view of the portion 700 along the cut line A-A′ of FIG. 7A. The cavities 701, which will be used for source and drain terminals, may be formed by an etching process as described above.

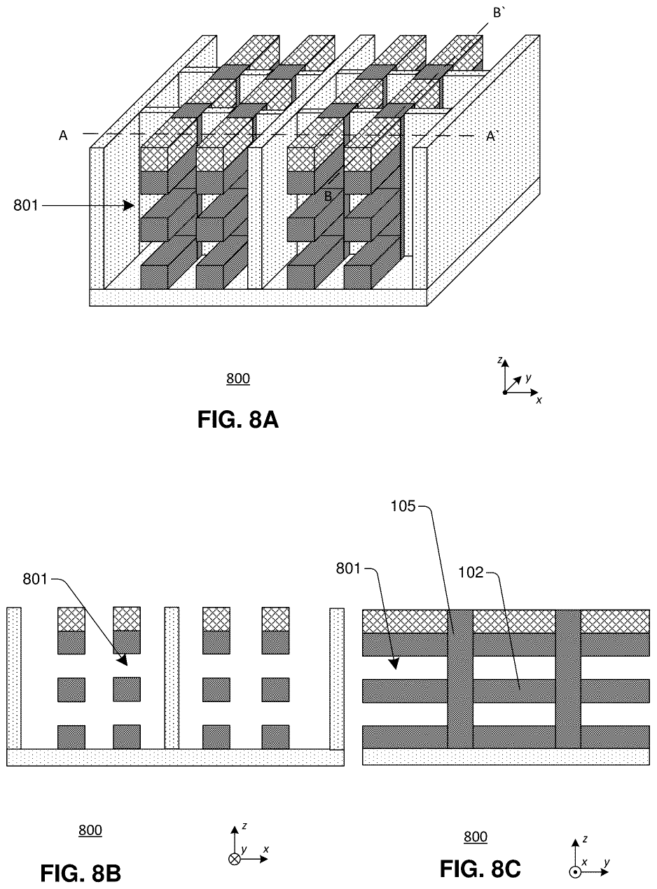

FIG. 8A illustrates a simplified oblique view of a portion 800, corresponding to the portion 700 of FIG. 7A after the removal of the remaining sections of sacrificial layers 202, leaving behind cavities 801. FIG. 8B illustrates a cross-sectional view of the portion 800 along the cut line A-A′ of FIG. 8A. FIG. 8C illustrates a cross-sectional view of the portion 800 along the cut line B-B′ of FIG. 8A. The sacrificial material may be removed by etching, e.g., wet etching with hot phosphoric acid, as described above. The removal of the sacrificial material leaves behind gate boards 102 supported by corresponding gate pillars 105.

FIG. 9 illustrates a simplified cross-sectional view of a portion 900 along the x-z plane, corresponding to the portion 800 of FIG. 8A after deposition of gate dielectric material 901 to coat at least the gate boards 102 and gate pillars 105. The gate dielectric material 901 may include any of the above-described gate dielectric materials. The deposition, which also coats other elements such as the base layer 110 and barrier 118, may be performed by ALD, CVD, or any other suitable deposition process. The gate dielectric material 901 may be said to form a conformal layer as it forms a relatively thin film of about 5nm that generally conforms to the shape of the existing elements of the portion 800. The gate dielectric material 901 includes a section of the gate dielectric layer 111 of FIG. 1, as well as sections that will be removed subsequently in the fabrication process.

FIG. 10 illustrates a simplified cross-sectional view of a portion 1000 along the x-z plane, corresponding to the portion 900 of FIG. 9 after deposition of channel material 1001 to coat the gate dielectric material 901, including the sections coating the gate boards 102. The deposition may be performed by ALD, CVD, or any other suitable deposition process. The channel material 1001 may be said to form a conformal layer as it forms a relatively thin film of about 5 nm that generally conforms to the chape of the existing elements of portion 900. The channel material 1001 includes sections of the channel layer 112 of FIG. 1, as well as sections that will be removed subsequently in the fabrication process.

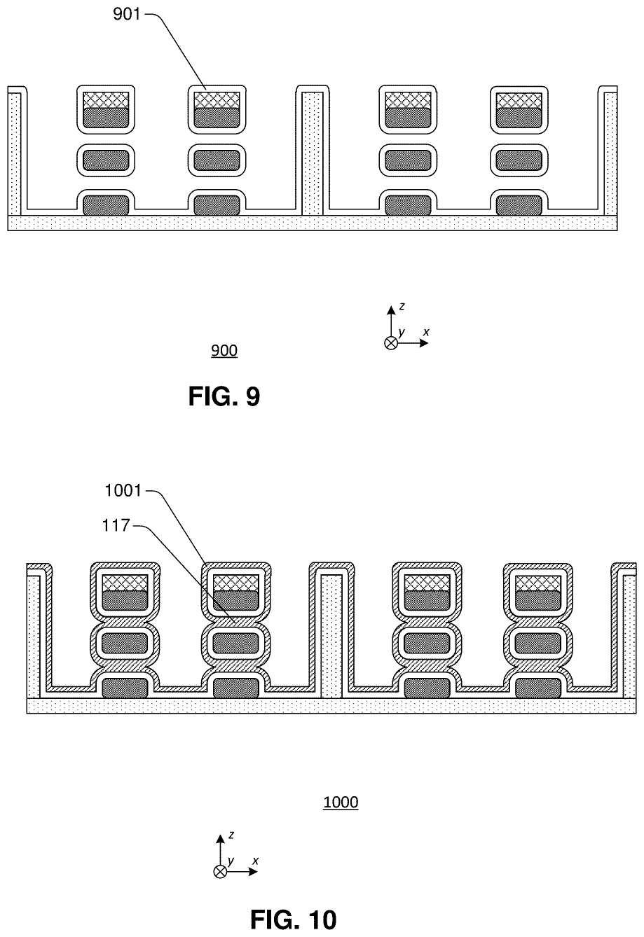

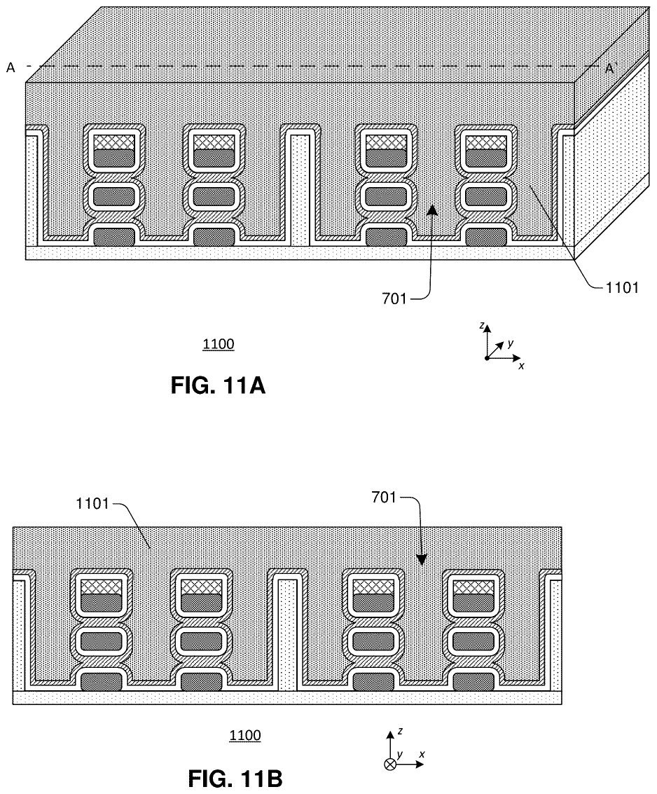

FIG. 11A illustrates a simplified oblique view of a portion 1100, corresponding to the portion 1000 of FIG. 10 after the deposition of conductive material 1101 to fill the cavities 701 for forming the source and drain terminals 113. FIG. 11B illustrates a cross-sectional view of the portion 1100 along the cut line A-A′ of FIG. 11A. The conductive material 1101, which may include any of the current-carrying terminal materials described above, may be deposited by any of the deposition processes described above. Since the extant channel and gate dielectric layers define the boundaries of the source and drain terminals, the source and drain terminals may be considered self-aligned and may be formed without requiring additional corresponding masks.

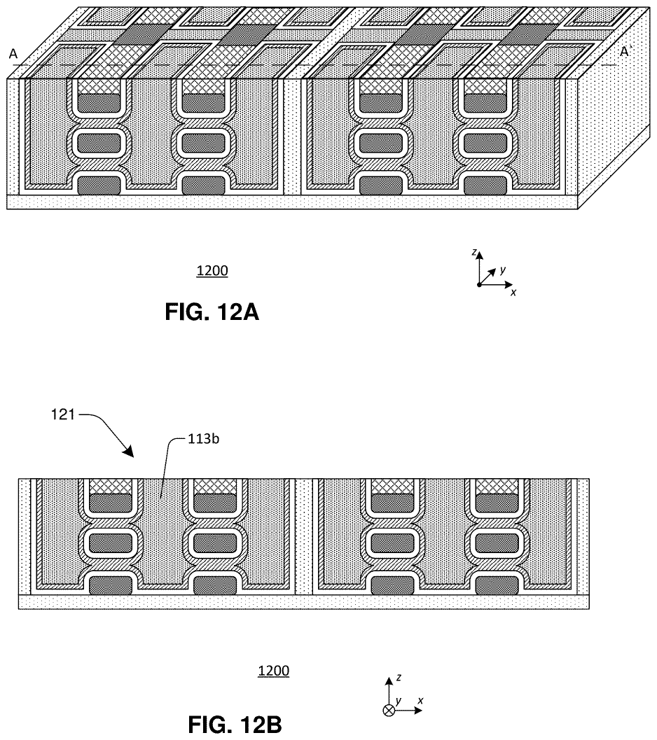

FIG. 12A illustrates a simplified oblique view of a portion 1200, corresponding to the portion 1100 of FIG. 11A after planarization (e.g., CMP). FIG. 12B illustrates a cross-sectional view of the portion 1200 along the cut line A-A′ of FIG. 12A. After the planarization, the cells correspond to cell 121 of FIG. 1B, having two FETs sharing a common drain terminal 113b.

As noted above, stacked FETs in accordance with some embodiments of the disclosure may be used in memory cell arrays. Some memory cells may be in the form of, for example, two transistors and zero capacitors (2T0C) or one transistor and one capacitor (1T1C). The memory state of the cell is stored by a so-called storage node comprising capacitive elements of the cell, whether an explicit capacitor as in the 1T1C memory cell or inherent capacitance of the transistor elements the 2T0C memory cell. Stacked FETs in accordance with embodiments of the disclosure may be used in both 1T1C memory arrays and 2T0C memory arrays.

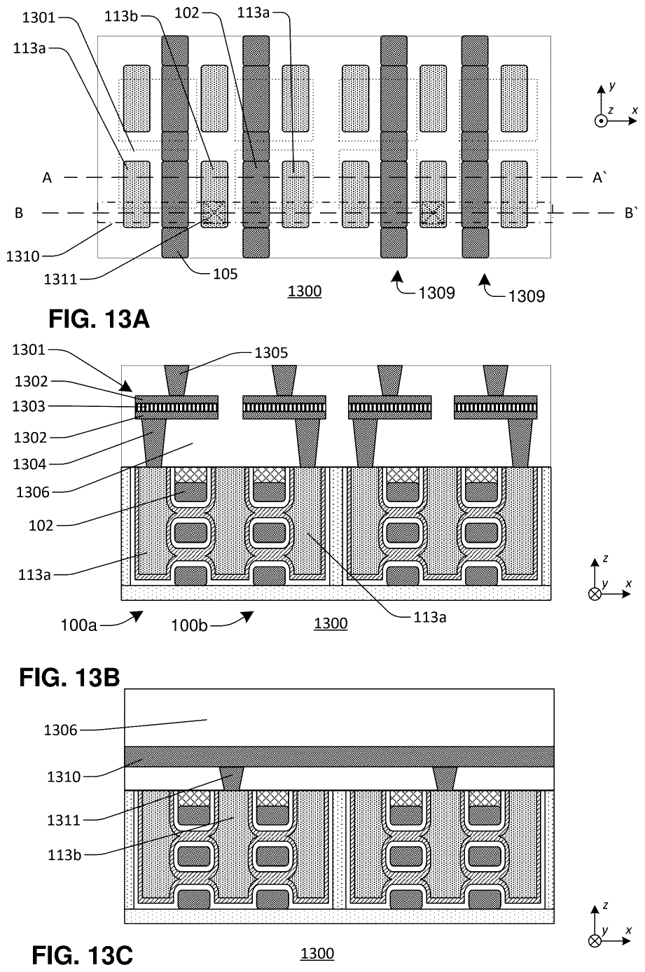

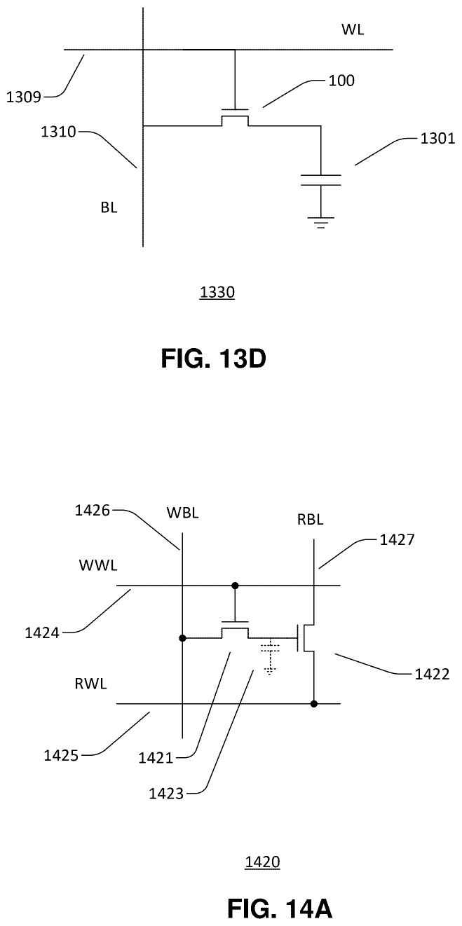

FIG. 13A illustrates a simplified partial plan view of a portion 1300, corresponding to the portion 1200 of FIG. 12A after formation of 1T1C memory cells using the FETs of the portion 1200. For improved clarity, FIG. 13A forgoes showing, for example, the outlines of the channel layer 112, the gate dielectric layer 111, and the hardmask board 116. FIG. 13B illustrates a simplified cross-sectional view of the portion 1300 along the cut line A-A′ of FIG. 13A. FIG. 13C illustrates a simplified cross-sectional view of the portion 1300 along the cut line B-B′ of FIG. 13A. The figures show one or more dielectric layers 1306 formed over the portion 1200 in which a number of example capacitors 1301 are formed. The dielectric layers 1306 may comprise, for example, any of the ILD materials listed above. A conductive via 1304 may comprise, for example, any of the conductive materials listed above.

Each example capacitor 1301 comprises two conductive plates 1302 separated by an insulator 1303. The conductive plates 1302 may comprise, for example, any of the conductive materials listed above. The insulator 1303 may comprise, for example, any of the dielectric materials listed above, such as, for example, any of the high-k dielectrics. A first plate 1302 connects to the source terminal 113a of the corresponding stacked FET 100, e.g., FET 100a, using via 1304. The second plate 1302 may connect to other circuitry (not shown) (e.g., reset circuitry) by a via 1305. The drain terminal 113b of each FET 100 is connected to a corresponding bitline 1310 of the memory array by a corresponding via 1311. Notably, the gate boards and gate pillars of cells contiguous in the y direction form conductively continuous wordlines 1309 for the memory cell array. The intersecting bitlines and wordlines of the memory array may form a grid.

Accordingly, each stacked FET 100 is at an intersection of a wordline 1309 and a bitline 1310. The wordline 1309 is configured to control the voltage of the gate stack of the FET 100 to allow (1) reading of the value stored by the corresponding capacitor 1301 to the bitline 1310 and (2) writing, or storing, of the value on the bitline 1310 to the corresponding capacitor 1301.

FIG. 13D illustrates a simplified circuit diagram of an example 1T1C memory cell 1330 that may, for example, correspond to the memory cells of the portion 1300 of FIGS. 13A, 13B, and 13C. The memory cell 1330, at the intersection of worldline 1309 and bitline 1310, comprising stacked FET 100 and capacitor 1301, is configured to operate as described above.

The operation of 2T0C memory cells is somewhat different. A 2T0C memory cell comprises a write transistor and a read transistor and lacks a separate capacitor. Rather than using a separate capacitor, a 2T0C capacitor relies on the inherent capacitance of the structure to store its data.

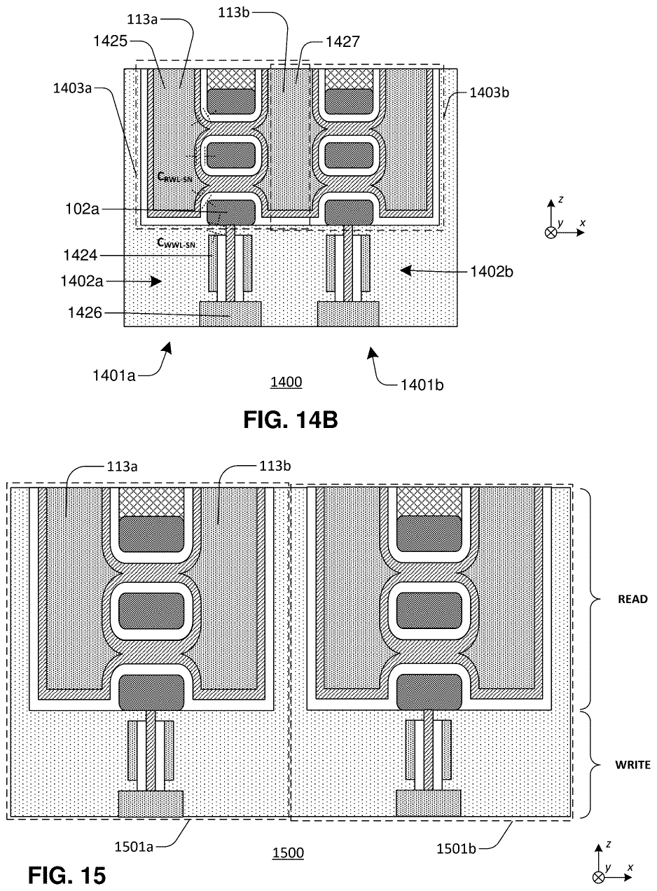

FIG. 14A illustrates a simplified circuit diagram of an example 2T0C memory cell 1420 that may correspond to example memory cells described below. The memory cell 1420 comprises write transistor 1421 and read transistor 1422. The inherent capacitance of the structure is represented as storage node 1423. The drain of the write transistor 1421 is connected to a write bitline (WBL) 1426, its gate is connected to a write wordline (WWL) 1424, and its source is connected to the gate of the read transistor 1422. The drain of the read transistor 1422 is connected to a read bitline (RBL) 1427 and its source is connected to a read wordline (RWL) 1425. When the WWL 1424 pulses on, the value on the WBL gets stored in the storage node of the memory cell 1420. When the voltage on the RWL 1425 is pulsed, the impact on the RBL 1427 depends on the state of the storage node and is measured to determine that state.

Specifically, if the storage node value is high, then there will be a relatively large on-state current though the read transistor 1422, but if the storage node value is low, then there will be a relatively very small off-state current through the read transistor 1422.

In addition to the capacitance of the storage node 1423, which may be referred to as C_{SN}, the read transistor 1422 is also subject to parasitic capacitances due to capacitive coupling between the storage node and the read and write wordlines, which may be referred to as C_{RWL-SN} and C_{WWL-SN}, respectively. Using a stacked FET, as described in this disclosure, for the read transistor 1422 in a 2T0C memory cell helps reduce overall parasitic capacitances and helps improve operating characteristics such as subthreshold swing, on-state current, and off-state current. In particular, a stacked FET may result in a sufficiently large reduction in C_{WWL-SN} such that overall parasitic capacitance is reduced even if C_{RWL-SN} slightly increases. Beneficially, the smaller coupling capacitance (e.g., C_{RWL-SN} and C_{WWL-SN}) and increased CsN capacitance results in a reduced V_{SN} voltage drop after a write due to coupling, which consequently makes it easier to distinguish a data high from a data low.

FIG. 14B illustrates a simplified cross-sectional view of an example memory array portion 1400 comprising a pair of 2T0C memory cells 1401 in accordance with some embodiments of the disclosure. A memory cell 1401 may correspond to a memory cell 1420 of FIG. 14A. Each memory cell 1401 (e.g., cells 1401a and 1401b) comprises a write transistor 1402 (e.g., transistors 1402a and 1402b) and a corresponding read transistor 1403 (e.g., read transistors 1403a and 1403b). The read transistors 1403a and 1403b are substantially similar to the stacked FETs 100a and 100b of FIG. 1B and similarly share a common drain terminal 113b. Notably, the gate boards 102 of a read transistor function as both the storage node for the memory cell 1401 and as the source terminal for the corresponding write transistor 1402.

FIG. 15 illustrates a simplified cross-sectional view of an example memory array portion 1500 that, in contrast to portion 1400, comprises two 2T0C memory cells—namely, memory cells 1501a and 1501b—whose read transistors do not share a drain terminal 113b. This implementation may be characterized as a split-drain implementation. A memory cell 1501 may correspond to a memory cell 1420 of FIG. 14A.

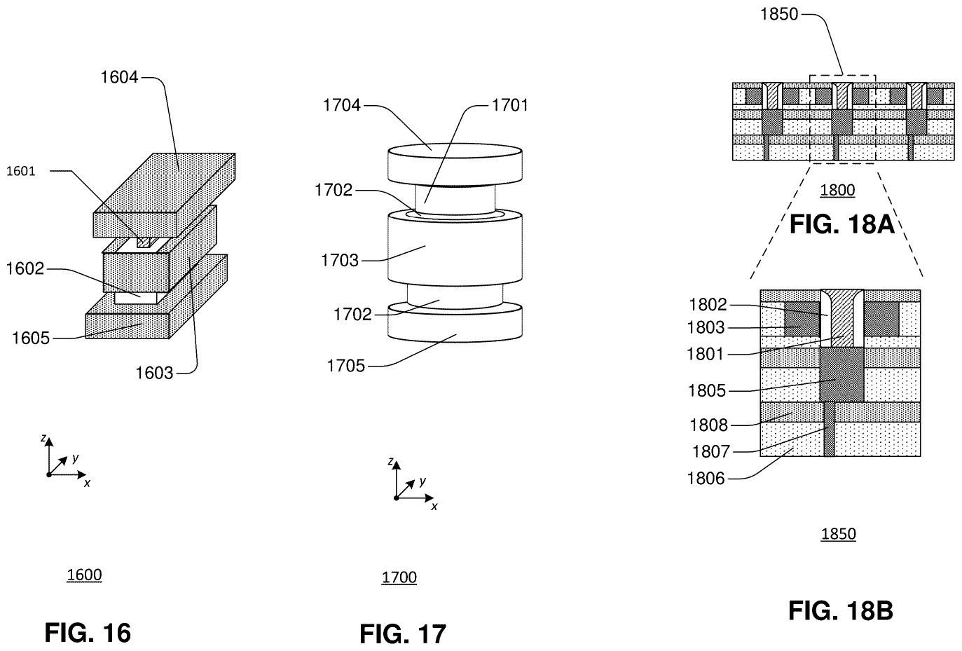

FIG. 16 illustrates a simplified oblique perspective view of an example FET 1600 corresponding to a write transistor 1402 of FIG. 14B. The FET 1600 is a finFET, comprising a fin-shaped channel 1601 separated from a surrounding gate 1603 by a high-k dielectric layer 1602 and connected between a source terminal 1604 and a drain terminal 1605. The source terminal 1604 may also be part of the storage node, while the drain terminal 1605 is connected to the write bitline and the gate 1603 is connected to the write wordline. The cross-sections of the elements of the FET 1600 in the x-y plane is substantially rectangular.

FIG. 17 illustrates a simplified oblique perspective view of an alternative example FET 1700 corresponding to a write transistor 1402 of FIG. 14B. The FET 1700 is substantially the same as the FET 1600 of FIG. 16, except that the cross sections of the corresponding elements—namely, channel 1701, gate 1703, high-k dielectric layer 1702, source terminal 1704, and drain terminal 1705—in the x-y plane are substantially oval.

FIGS. 18-20 show simplified views of various example stages of manufacture of portions of an example integrated circuit (IC) device in accordance with some embodiments of the disclosure, provided with the same caveats as provided above in references to FIGS. 2-13. Specifically, FIGS. 18-20 illustrate some steps in the manufacture of an example memory array comprising memory cells such as memory cells 1401 of FIG. 14B. The manufacture of the stacked FETs is substantially similar to the manufacture of the stacked FETs 100 shown in FIGS. 2-12, except that (1) the base layer comprises the write transistors, which connect to the gate stacks of the read transistors and (2) the gate pillars do not extend in the y-direction to conductively connect the gates of adjoining stacked FETs since the gate stacks do not form a wordline. Accordingly, for simplicity, in view of the similarities, corresponding elements in FIGS. 18-20 are similarly shown and shaded as in FIGS. 2-12 and are not individually described and labeled.

FIG. 18A illustrates a simplified cross-sectional view of a portion 1800 of an example base layer comprising write transistors such as FET 1850. FIG. 18B illustrates an enlargement focusing on FET 1850 of FIG. 18A. FET 1850 comprises elements fabricated in ILD layers 1806 (e.g., silicon dioxide) separated by separation layers 1808 (e.g., aluminum oxide). Drain terminal 1805 (e.g., metal), which may be part of a word bitline, connects to other circuit elements by via 1807 (e.g., metal) and is configured to connect to the source terminal (the gate stack of the read transistor, not shown) through a channel 1801 (e.g., semiconductor). The channel 1801 is separated from the surrounding gate 1803, which may be part of a write wordline, by high-k dielectric layer 1802. The dielectric layer 1802 may be formed using an etch-back process, as used for fabricating sidewall spacers, resulting in a funnel-like cross section for the dielectric layer 1802.

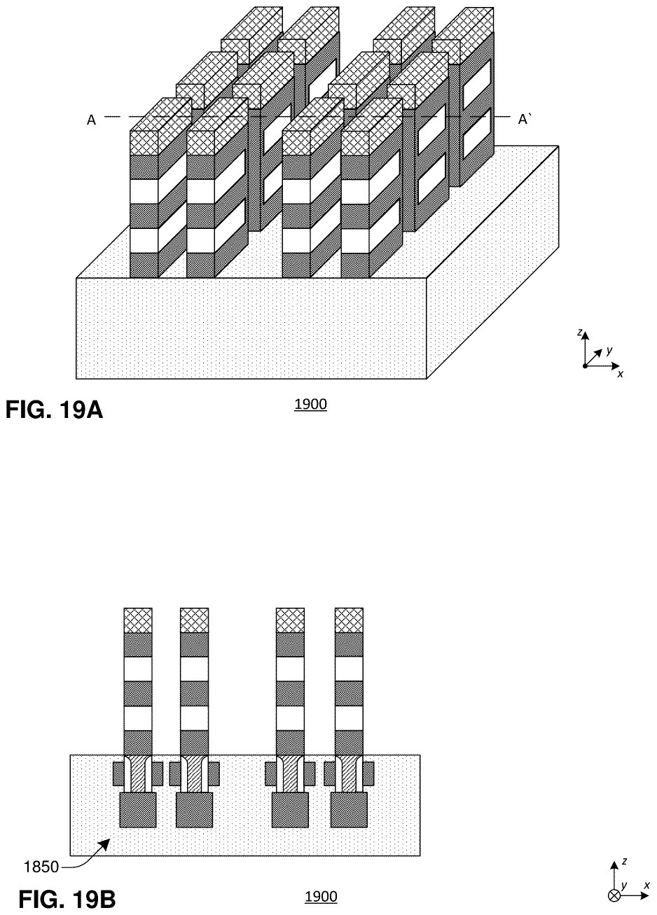

FIG. 19A illustrates a simplified oblique view of a portion 1900, corresponding to the portion 1800 of FIG. 18A following steps corresponding to FIGS. 2-5 above, namely deposition of layers of gate material, sacrificial material, and hardmask material, etching of a first set and a second set of trenches, and formation of gate pillars. As noted above, the gate pillars are separated by gaps in the y-direction from the gate pillars of adjoining stacked FETs. FIG. 19B illustrates a simplified cross-sectional view of the portion 1900 along cut line A-A′ of FIG. 19A.

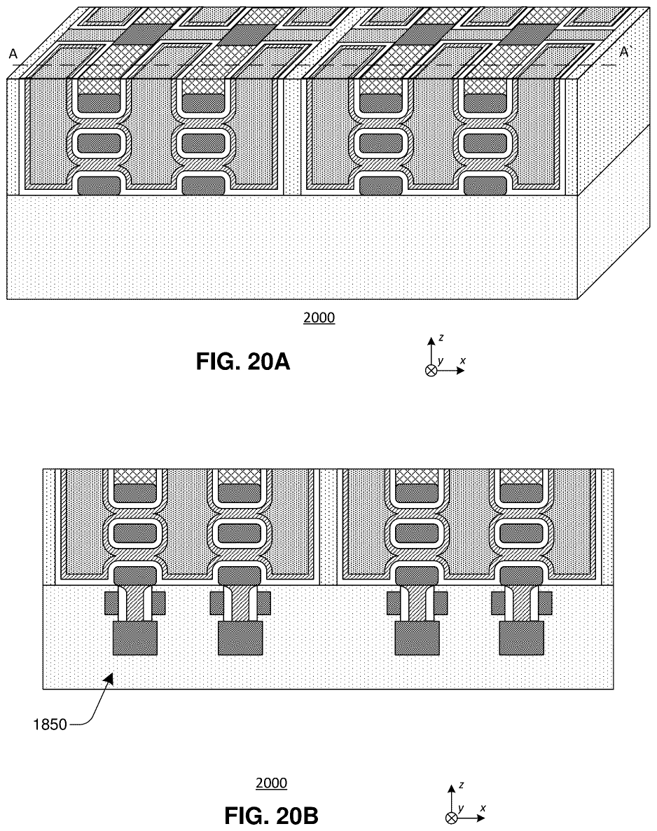

FIG. 20A illustrates a simplified oblique view of a portion 2000, corresponding to the portion 1900 of FIG. 19A following steps corresponding to FIGS. 6-12 above, namely oxide deposition, planarization, source/drain terminal cavities etching, gate release via selective etching, depositions of dielectric material, channel material, and source/drain material, and planarization. FIG. 20B illustrates a simplified cross-sectional view of the portion 2000 along cut line A-A′ of FIG. 20A. The portion 2000 comprises memory cells substantially corresponding to example memory cells 1401 of FIG. 14.

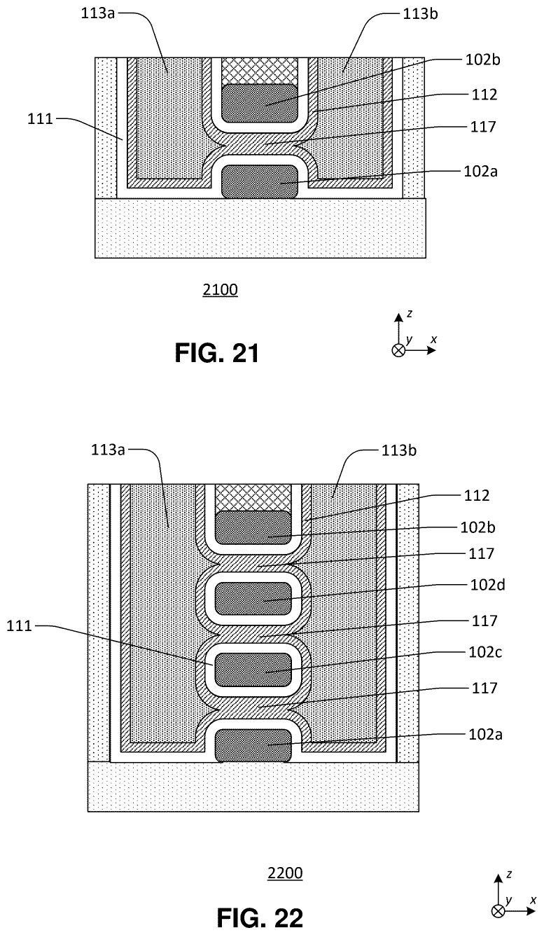

FIG. 21 illustrates a simplified cross-sectional view of an example cell 2100 in accordance with an alternative embodiment of the disclosure. While the example cell 120 of FIG. 1A and the example cell 121 of FIG. 1B each had intermediary gate boards 102c, the cell 2100 lacks any intermediary gate boards and includes only a bottom gate board 102a and a top gate board 102b. Consequently, the channel layer 112 includes only one channel band 117 disposed between the gate boards 102a and 102b, connecting source terminal 113a to drain terminal 113b.

FIG. 22 illustrates a simplified cross-sectional view an example cell 2200 in accordance with another alternative embodiment of the disclosure. While the example cell 120 of FIG. 1A and the example cell 121 of FIG. 1B each had one intermediary gate board 102c, the cell 2200 includes an additional intermediary gate board 102d. Consequently, the channel layer 112 includes three channel bands 117 disposed between pairs of gate boards 102, connecting source terminal 113a to drain terminal 113b. Other alternative embodiments may have any number of additional intermediary gate boards 102 and corresponding additional channel bands 117.

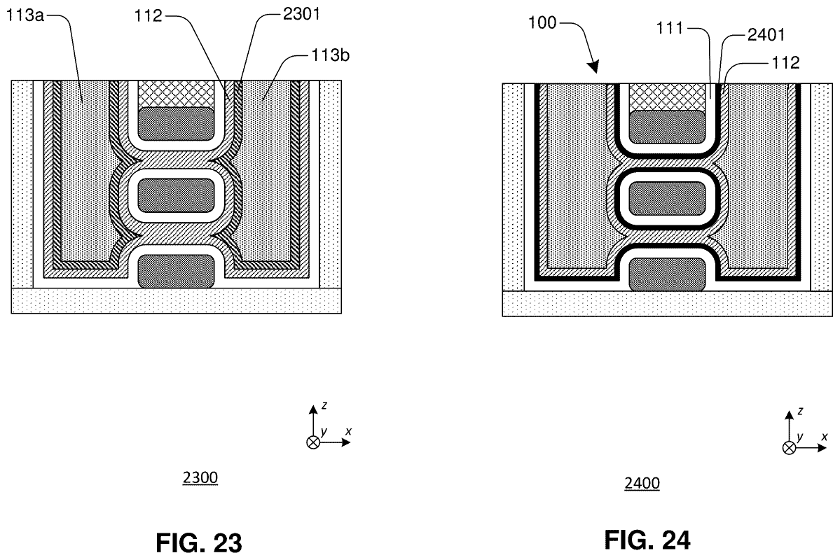

FIG. 23 illustrates a simplified cross-sectional view of an example cell 2300 in accordance with an alternative embodiment of the disclosure. The cell 2300 includes a thin conformal dopant soak layer 2301 deposited over the channel layer 112, separating it from the source terminal 113a and the drain terminal 113b. The dopant soak layer 2301, which may be deposited using, e.g., ALD or CVD, improves the interface between the metal-oxide-semiconductor channel layer 112 and the metal source and drain terminal 113. The dopant soak layer 2301 may comprise, for example, for an n-type channel layer 112, a metal oxide material doped with hydrogen.

FIG. 24 illustrates a simplified cross-sectional view of an example cell 2400 in accordance with an alternative embodiment of the disclosure. The cell 2400 includes a thin dipole layer 2401 on the surface of the dielectric layer 111 interfacing with the channel layer 112. The dipole layer 2401 is created by a treatment of the dielectric layer 111 that forms a dipole layer on its surface, where the dipole layer 2401 modifies the threshold voltage of the FET 100 of the cell 2400. The treatment may comprise, for example, a diffusion of oxygen ions from PECVD, H₂O₂ oxidation, and/or nitric acid oxidation. Note that the dipole layer 2401 may modify additional characteristics of the channel layer (e.g., dominant charge carriers), depending on the particular makeup of the channel layer and the type of dipole layer.

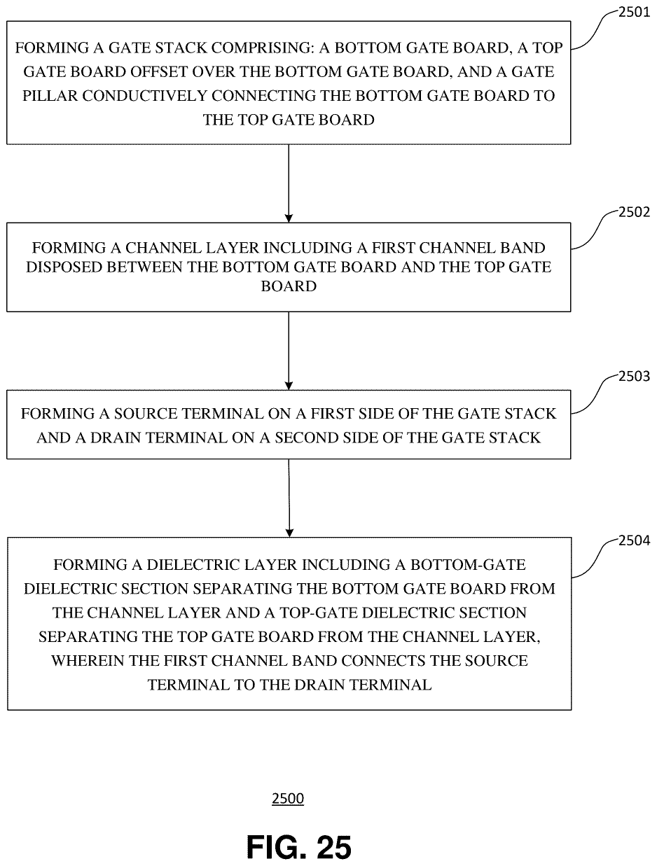

FIG. 25 is a flowchart illustrating an example method 2500 of forming an IC device in accordance with some embodiments of the disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included. Acts can correspond, for example, to the structures previously illustrated in FIGS. 2-12 in some embodiments.

Act 2501 includes, for each cell of an array of integrated circuit (IC) cells, forming a gate stack having a bottom gate board, a top gate board offset over the bottom gate board, and a gate pillar conductively connecting the bottom gate board to the top gate board. FIGS. 2-8 illustrate views of some embodiments corresponding to act 2501.

Act 2502 includes, for each cell, forming a channel layer including a first channel band disposed between the bottom gate board and the top gate board. FIG. 10 illustrates a view of an embodiment corresponding to act 2502.

Act 2503 includes, for each cell, forming a source terminal on a first side of the gate stack and a drain terminal on a second side of the gate stack. FIGS. 11-12 illustrate views of some embodiments corresponding to act 2503.

Act 2504 includes, for each cell, forming dielectric layer including a bottom-gate dielectric section separating the bottom gate board from the channel layer and a top-gate dielectric section separating the top gate board from the channel layer, wherein the first channel band connects the source terminal to the drain terminal. FIGS. 1A and 9 illustrate view of some embodiments corresponding to act 2504.

Accordingly, in some embodiments, the present disclosure relates to an integrated circuit (IC) device having an array of cells. Each cell of the array includes a stacked field-effect transistor (FET). The stacked FET includes a gate stack having a bottom gate board, a top gate board offset over the bottom gate board, and a gate pillar conductively connecting the bottom gate board to the top gate board. The FET further includes a channel layer including a first channel band disposed between the bottom gate board and the top gate board, a source terminal located on a first side of the gate stack, a drain terminal located on a second side of the gate stack, and a dielectric layer including a bottom-gate dielectric section separating the bottom gate board from the channel layer and a top-gate dielectric section separating the top gate board from the channel layer. The first channel band connects the source terminal to the drain terminal. The gate stack is configured to control the conductivity of the first channel band.

In other embodiments, the present disclosure relates to a method including forming an integrated circuit (IC) device having an array of cells, each cell of the array having a stacked field-effect transistor (FET). Forming the stacked FET of each cell includes forming a gate stack having a bottom gate board, a top gate board offset over the bottom gate board, and a gate pillar conductively connecting the bottom gate board to the top gate board. Forming the FET also includes forming a channel layer including a first channel band disposed between the bottom gate board and the top gate board, forming a source terminal on a first side of the gate stack, forming a drain terminal on a second side of the gate stack, and forming a dielectric layer including a bottom-gate dielectric section separating the bottom gate board from the channel layer and a top-gate dielectric section separating the top gate board from the channel layer. The first channel band connects the source terminal to the drain terminal. The gate stack is configured to control the conductivity of the first channel band.

In yet other embodiments, the present disclosure relates to a method including: forming alternating layers of gate-stack metal and sacrificial material over an insulator layer of an integrated circuit (IC) device, etching the gate-stack metal and sacrificial material layers to form a first set of trenches, filling the first set of trenches with metal to form gate pillars, etching the gate-stack metal and sacrificial material layers to form a second set of trenches perpendicular to the first set of trenches, filling the second set of trenches with dielectric, etching cavities in the dielectric for source and drain terminals, removing sacrificial material to perform gate release of a plurality of gate boards supported by corresponding gate pillars, depositing a gate dielectric to coat the gate boards and gate pillars, depositing a channel material to coat the gate dielectric coating the gate boards, depositing conductive material to fill the cavities for forming source and drain terminals, and planarizing the IC device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated circuit (IC) device comprising an array of cells, each cell of the array comprising a stacked field-effect transistor (FET), wherein the stacked FET comprises:
a gate stack comprising:
a bottom gate board;
a top gate board offset over the bottom gate board; and
a gate pillar conductively connecting the bottom gate board to the top gate board;
a channel layer including a first channel band disposed between the bottom gate board and the top gate board;
a source terminal located on a first side of the gate stack and a drain terminal located on a second side of the gate stack; and
a dielectric layer including a bottom-gate dielectric section separating the bottom gate board from the channel layer and a top-gate dielectric section separating the top gate board from the channel layer, wherein the first channel band connects the source terminal to the drain terminal.

2. The IC device of claim 1, wherein:
the stacked FET further comprises a first intermediary gate board;
the first intermediary gate board is:
offset over the bottom gate board and under the top gate board; and
conductively connected to the gate pillar;
the channel layer includes a second channel band disposed between the first intermediary gate board and top gate board;
the second channel band connects the source terminal to the drain terminal;
the dielectric layer includes a first intermediary gate dielectric section; and
the first intermediary gate dielectric section separates the first intermediary gate board from the channel layer.

3. The IC device of claim 2, wherein:
the stacked FET further comprises one or more additional intermediary gate boards;
each additional intermediary gate board is:
offset over a lower intermediary gate board and under the top gate board; and
conductively connected to the gate pillar;
the channel layer includes one or more additional channel bands disposed over the additional intermediary gate boards;
each of the one or more additional channel bands connects the source terminal to the drain terminal;
the dielectric layer includes corresponding intermediary gate dielectric sections; and
each corresponding intermediary gate dielectric section separates one additional intermediary gate board from the channel layer.

4. The IC device of claim 1, wherein:
the stacked FET further comprises a hardmask board overlying the top gate board; and
the hardmask board is separated from the source and drain terminals by the top-gate dielectric section and the channel layer.

5. The IC device of claim 1, wherein:
the top gate board is separated from the source and drain terminals by the top-gate dielectric section and the channel layer; and
the bottom gate board is separated from the source and drain terminals by the bottom-gate dielectric section and the channel layer.

6. The IC device of claim 1, wherein the array of cells is formed over an insulator layer of the IC device.

7. The IC device of claim 1, wherein the channel layer comprises a metal-oxide semiconductor.

8. The IC device of claim 1, wherein:
the stacked FET is a first stacked FET;
each cell further comprises a second stacked FET comprising a corresponding second gate stack and a corresponding second source terminal;
the corresponding second gate stack of the second stacked FET is configured to be operable independently of the gate stack of the first stacked FET; and
the drain terminal of the first stacked FET forms a shared drain terminal for the second stacked FET.

9. The IC device of claim 1, wherein:
the array of cells is a memory array; and
each cell further comprises a capacitor conductively connected to the source terminal and is configured as a one-transistor one-capacitor (1T1C) memory cell.

10. The IC device of claim 9, wherein:
the memory array comprises a grid of wordlines and bitlines;
each cell connects to a corresponding wordline and a corresponding bitline; and
the gate stack of the stacked FET is conductively connected to a set of gate stacks of other stacked FETs connected to the corresponding wordline.

11. The IC device of claim 1, wherein:
the array of cells is a memory array;
each cell is configured as a two-transistor zero-capacitor (2T0C) memory cell comprising a read transistor and a write transistor;
the stacked FET is configured to be the read transistor;
the write transistor comprises a gate terminal, a source terminal, a channel, and a drain terminal; and
the gate stack is connected to the channel of the write transistor and configured to function as the source terminal of the write transistor.

12. The IC device of claim 1, further comprising a dopant soak layer disposed between the channel layer and the source and drain terminals.

13. The IC device of claim 1, wherein the dielectric layer comprises a dipole surface layer in contact with the channel layer.

14. A method comprising forming an integrated circuit (IC) device comprising an array of cells, each cell of the array comprising a stacked field-effect transistor (FET), wherein forming the stacked FET of each cell comprises:
forming a gate stack comprising:
a bottom gate board;
a top gate board offset over the bottom gate board; and
a gate pillar conductively connecting the bottom gate board to the top gate board;
forming a channel layer including a first channel band disposed between the bottom gate board and the top gate board;
forming a source terminal on a first side of the gate stack and a drain terminal on a second side of the gate stack; and
forming a dielectric layer including a bottom-gate dielectric section separating the bottom gate board from the channel layer and a top-gate dielectric section separating the top gate board from the channel layer, wherein the first channel band connects the source terminal to the drain terminal.

15. The method of claim 14, wherein the channel layer comprises a metal-oxide semiconductor.

16. The method of claim 14, wherein forming the stacked FET further comprises forming a hardmask board overlying the top gate board, wherein the hardmask board is separated from the source and drain terminals by the top-gate dielectric section and the channel layer.

17. The method of claim 14, wherein forming the stacked FET further comprises:
forming one or more additional intermediary gate boards, wherein:
each intermediary gate board is:
offset over the bottom gate board and under the top gate board; and
conductively connected to the gate pillar;
the channel layer includes one or more additional channel bands disposed over the additional intermediary gate boards;
each of the one or more additional channel bands connects the source terminal to the drain terminal; and
the dielectric layer includes corresponding intermediary gate dielectric sections separating the intermediary gate board from the channel layer.

18. The method of claim 14, wherein:
the stacked FET is a first stacked FET;
each cell further comprises a second stacked FET;
forming the second stacked FET comprises forming a corresponding second gate stack and a corresponding second source terminal;
the corresponding second gate stack of the second stacked FET is configured to be operable independently of the gate stack of the first stacked FET; and
the drain terminal of the first stacked FET is configured to function as a shared drain terminal for the second stacked FET.

19. A method comprising:
forming alternating layers of gate-stack metal and sacrificial material over an insulator layer of an integrated circuit (IC) device;
etching the gate-stack metal and sacrificial material layers to form a first set of trenches;
filling the first set of trenches with metal to form gate pillars;
etching the gate-stack metal and sacrificial material layers to form a second set of trenches perpendicular to the first set of trenches;
filling the second set of trenches with dielectric;
etching cavities in the dielectric for source and drain terminals;
removing sacrificial material to perform gate release of a plurality of gate boards supported by corresponding gate pillars;
depositing a gate dielectric to coat the gate boards and gate pillars;
depositing a channel material to coat the gate dielectric coating the gate boards;
depositing conductive material to fill the cavities for forming source and drain terminals; and
planarizing the IC device.

20. The method of claim 19, wherein the channel material comprises a metal-oxide semiconductor.
